(19) United States
(12) Patent Application Publication
(10) Pub. No.: US 2011/0088685 A1
(43) Pub. Date: Apr. 21, 2011

(54) SOLAR DISH COLLECTOR SYSTEM AND ASSOCIATED METHODS

(76) Inventors: Dale E. Polk, SR., Titusville, FL (US); Dale E. Polk, JR., Titusville, FL (US)

(21) Appl. No.: 12/904,695

(22) Filed: Oct. 14, 2010

Related U.S. Application Data
(60) Provisional application No. 61/252,372, filed on Oct. 16, 2009.

(51) Int. Cl. F24J 2/04; F24J 2/38; F24J 2/13; H01L 31/0232

(52) U.S. Cl. 126/573; 126/634; 126/689; 136/246

(57) ABSTRACT

A solar dish collector system includes a solar dish collector panel for reflecting sunlight, and a conduit adjacent the solar dish collector panel. The conduit includes a supply tube to provide fluid to be heated by the reflected sunlight, and a return tube to return the heated fluid. A collector encloses open ends of the supply and return tubes, and is positioned to receive the reflected sunlight from the solar dish collector panel. The fluid from the supply tube at least partially fills the collector and is heated by the reflected sunlight while circulating therein. The heated fluid is then returned via the return tube.

### RELATED APPLICATION

This application claims the benefit of U.S. Provisional Application Ser. No. 61/252,372 filed Oct. 16, 2009, the entire contents of which are incorporated herein by reference.

### FIELD OF THE INVENTION

The present invention relates to the field of solar energy collector systems, and more particularly, to a solar dish collector system and related methods.

### BACKGROUND OF THE INVENTION

There are a variety of solar energy collector systems available for converting solar energy into other forms of energy that can be more readily used or stored. For example, concentrating collectors focus or concentrate the sun's radiation energy in a particular area.

One type of concentrating collector is the parabolic trough collector. A parabolic trough collector uses an elongated reflective trough having a parabolic cross-section to concentrate the sun's radiation along a focal line extending through the focal points of the parabolic elements of the trough. A conduit is positioned along the focal line and a heat transfer liquid is circulated through the conduit, where it will be heated by the sun's energy. Satisfactory flow rates at high temperatures can be obtained from these collectors.

With the assistance of a tracking system, parabolic trough collectors can become very efficient as they follow the movement of the sun. As solar energy collector systems incorporating parabolic type collectors are used to satisfy larger energy requirements, they become physically larger. As the parabolic trough solar collector panel increases in size, so does the cost and weight associated with holding and rotating the panel.

Another contributing factor towards cost is the conduit positioned along the focal line of the parabolic trough solar collector panel. The conduit typically includes a glass collector tube that is fragile, and has a high cost associated therewith. Even in view of the advances made in parabolic trough solar energy collectors, there is still a need for a low cost, lightweight and efficient solar energy collector system.

### SUMMARY OF THE INVENTION

In view of the foregoing background, it is therefore an object of the present invention to provide a solar energy collector system that overcomes the shortfalls of a parabolic trough solar energy collector.

This and other objects, advantages and features in accordance with the present invention are provided by a solar dish collector system comprising a solar dish collector panel for reflecting sunlight, and a conduit adjacent the solar dish collector panel. The conduit may comprise a supply tube to provide fluid to be heated by the reflected sunlight, and a return tube to return the heated fluid.

A collector may enclose open ends of the supply and return tubes, and the collector may be positioned to receive the reflected sunlight from the solar dish collector panel. The fluid from the supply tube may at least partially fill the collector and is heated by the reflected sunlight while circulating therein. The heated fluid may be returned via the return tube.

The solar dish collector panel may be configured to reflect the sunlight to a focal point, and the collector may be positioned at the focal point. The conduit may extend below the solar dish collector panel, and the supply and return tubes of the conduit may extend upwards through the solar dish collector panel.

The solar dish collector panel may be coupled to the conduit. The solar dish collector system may further comprise at least one actuator coupled to the conduit for pivotally rotating the conduit so that the solar dish collector panel tracks position of the sun.

The conduit advantageously functions as a fluid transfer device, supports the solar dish collector panel, and can be rotated based on the position of the sun in order for the solar dish collector panel to receive the maximum sunlight. Since the collector receives the reflected sunlight to heat the fluid circulating therein, the conduit does not need to be a glass tube. A glass tube is costly and fragile. Instead, the conduit may be an insulated tube or pipe, for example.

The collector may be configured as a sphere that may comprise a clear material on sides thereof to receive the reflected sunlight, and an opaque coating on a top portion thereof to prevent the reflected sunlight from escaping. The open ends of the supply and return tubes may be spaced apart from one another within the collector, with the open end of the supply tube being positioned below the open end of the return tube. This allows the incoming fluid to circulate within the collector from the bottom and exit from the top.

The collector may comprise glass, for example. In this embodiment, the solar dish collector system may further comprise a protective top over the collector for protection thereof. In addition, the solar dish collector system may further comprise a photovoltaic cell within the collector for generating electricity.

To increase solar consumption within the collector, the solar dish collector system may further comprise an interior collector positioned within the collector for receiving the reflected sunlight, and for directly contacting the fluid. The interior collector may be opaque, for example. The outer surfaces of the interior collector may comprise at least one of dimpled and corrugated outer surfaces to provide an increased surface area for contacting the fluid circulating within the collector. Moreover, the interior collector may be hollow and include a plurality of openings therethrough to further increase the surface area for contacting the fluid circulating within the collector.

The solar dish collector panel may comprise a reflective surface comprising at least one of a reflective film and a reflective coating. The solar dish collector system may further comprise at least one tilting device coupled to the at least one actuator for adjusting a latitudinal angle of the at least one conduit with respect to ground.

Another aspect is directed to a method for collecting solar energy using a solar energy collector system as defined above. The method may comprise reflecting sunlight using a solar dish collector panel. A conduit may be positioned adjacent the solar dish collector panel that comprises a supply tube to provide fluid to be heated by the reflected sunlight, and a return tube to return the heated fluid. The method may further comprise enclosing open ends of the supply and return tubes using a collector positioned to receive the reflected sunlight from the solar dish collector panel. The fluid from the supply tube may at least partially fill the collector and be heated by the reflected sunlight while circulating therein. The heated fluid may then be returned via the return tube.

### BRIEF DESCRIPTION OF THE DRAWINGS

FIG. 1 is a schematic diagram of a solar dish collector system in accordance with the present invention.

FIG. 2 is a partial schematic diagram of the collector illustrated in FIG. 1.

FIG. 3 is a schematic diagram of the solar dish collector system illustrated in FIG. 1 with additional features.

FIG. 4 is a schematic diagram of another embodiment of a solar dish collector system in accordance with the present invention.

FIG. 5 is a schematic diagram of solar dish collector systems connected together in series in accordance with the present invention.

FIG. 6 is a flowchart illustrating a method for collecting solar energy using a solar dish collector system in accordance with the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternative embodiments.

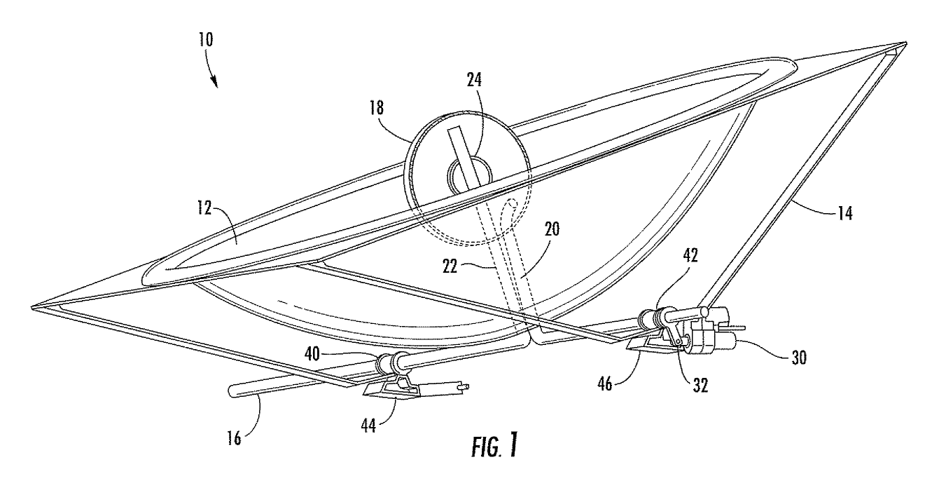

Referring initially to FIG. 1, a solar dish collector system 10 comprises a solar dish collector panel 12 carried by a base 14. The base 14 is mounted to a conduit 16 that carries a fluid that is to be heated by the sunlight reflected from the solar dish collector panel 12. The fluid may be oil or water, for example.

The solar dish collector panel 12 is coated with a reflective material for directing sunlight to a central point. In the illustrated solar dish collector system 10, sunlight is directed to a collector 18 that is positioned at the central point. Fluid from the conduit 16 passes through the collector 18 for heating. The illustrated collector 18 is a clear sphere coupled to the conduit 16. Although the collector 18 is illustrated as a sphere, other shapes may be used.

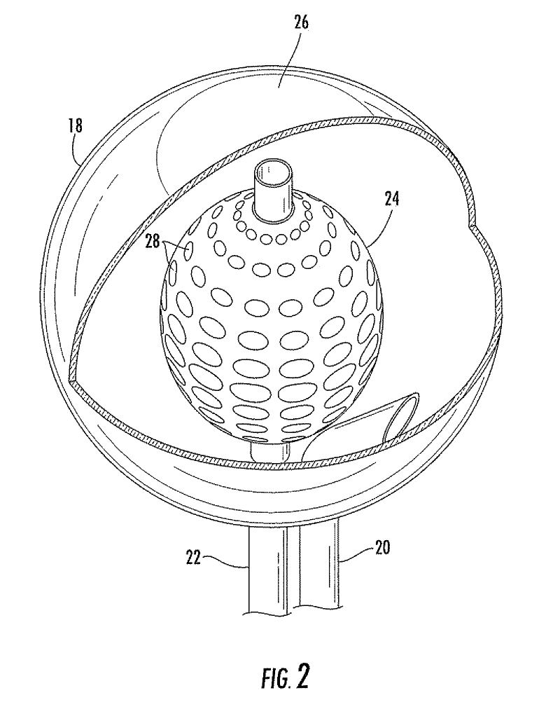

As illustrated in FIG. 2, the conduit 16 routes fluid to the collector 18 via a supply tube 20. Fluid is returned to the conduit 16 via a return tube 22. As the fluid enters the collector 18 via the supply tube 20, the fluid circulates within the collector. Once the fluid fills the collector 18 and reaches an opening of the return tube 22, the fluid is then returned to the conduit 16.

While circulating within the collector 18, the fluid is heated by the sunlight reflected from the solar dish collector panel 12. To increase solar consumption within the collector 18, a dark colored interior collector 24 may be placed within the collector. The interior collector 24 is placed around the return tube 22, and is preferably black for insuring that the sunlight reflected from the solar dish collector panel 12 remains within the collector 18 for heating the fluid. In other embodiments, the interior collector 24 may be placed separate from the return tube 22.

Since sunlight enters from the sides of the collector 18, a top portion 26 of the collector may be black to prevent the entered sunlight from escaping. Consequently, the black top portion 26 reflects the sunlight. To keep the reflected sunlight within the collector, the sides of the collector 18 may be silver. Separately or in addition to the black and silver coatings, a one-way film may be applied to the collector 18. A function of the one-way film is to allow sunlight in but not let it escape. These features advantageously increase solar absorption by the collector 18.

Although the interior collector 24 is illustrated as a sphere, other shapes may be used. The interior collector 24 may be hollow and include a plurality of openings 28 therethrough. This provides a greater surface area in which the interior collector 24 can contact the fluid for heating thereof. In lieu of openings 28, the interior collector 24 may be dimpled or corrugated, for example.

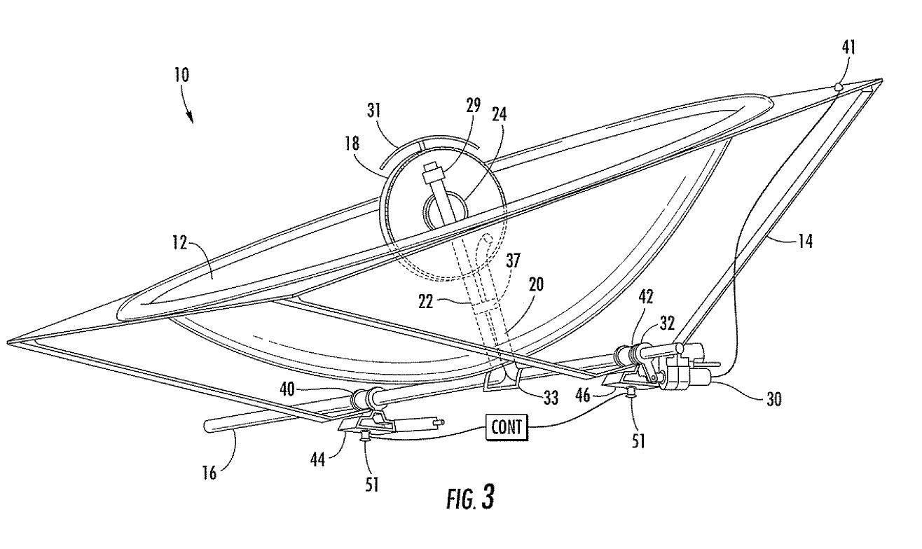

The return tube 22 may also have a photovoltaic cell 29 associated therewith, as illustrated in FIG. 3. The photovoltaic cell 29 may have a flat or circular design, for example. In this configuration, the solar dish collector system 10 not only heats the fluid within the conduit 16, but also generates electricity. An added benefit of the photovoltaic cell 29 contacting the fluid within the collector 18 is that the fluid cools the photovoltaic cell 29 as it is being heated by the sunlight magnified by the solar dish collector panel 12.

In one embodiment, the collector 18 is glass. As readily appreciated by those skilled in the art, other types of transparent materials may be used. When the collector 18 is glass or some other delicate material, a clear umbrella cap 31 comprising a non-delicate material may be placed on top of the collector 18 for protection from high winds and flying debris. In one embodiment, the cap 31 is directly attached to the top portion 26 of the collector 18. In other embodiments, the cap 31 may be attached to the solar dish collector panel 12 or to one or both of the supply and return tubes 20, 22.

The conduit 16 may be an insulated pipe or tube as readily appreciated by those skilled in the art. The pipe or tube may be cast iron or plastic, for example, although other types of material may be readily used. An advantage of the insulated pipe or tube is that it is less expensive and more durable as compared to a glass conduit normally associated with a parabolic type collector. In a parabolic type collector, the glass conduit runs along a focal line, which extends the length of the parabolic type collector. In contrast, the glass collector 18 is at a focal point of the solar dish collector system 10.

Since the base 14 of the solar dish collector system 10 is mounted to the conduit 16, rotation of the conduit causes the solar dish collector panel 12 to be rotated. In other words, the conduit 16 is the pivot point. The base 14 is mounted to the conduit 16 at connection points 40 and 42. The connection points 40 and 42 also include conduit supports 44 and 46 for elevating the conduit 16 above ground.

Still referring to FIG. 3, an actuator 30 is coupled to an arm 32 that is coupled to the conduit 16. As the actuator 30 moves the arm 32, the solar dish system 10 is rotated. To insure that the supply and return tubes 20, 22 rotate together, they may be coupled together. The coupling 33 may be where the supply and return tubes 20, 22 split off from the conduit 16. In addition to or in lieu of, a different coupling 37 for the supply and return tubes 20, 22 may be within the solar dish collector panel 12 itself, closer to the collector 18.

The solar dish system 10 is rotated to track position of the sun. One or more sensors 41 are used to determine position of the solar dish collector system 10 with respect to the sun. An output signal from each sensor 41 is applied to an actuator 30. Since the solar dish system 10 is mounted to the conduit 16, a chain or belt driven motor is not needed as with a parabolic type collector. This also advantageously reduces weight and cost.

The base 14 and solar dish collector panel 12 may be formed out of a molding material comprising a thermoplastic material or a thermosetting material, as readily appreciated by those skilled in the art. The molding material may be based on a polymer or elastomer. The polymers may also be fiber-reinforced. Other types of plastic composites may be used, as readily appreciated by those skilled in the art. In addition, the base 14 and solar dish collector panel 12 may be formed out of metal.

The solar dish collector panel 12 has a reflective surface for directing the sunlight toward the clear collector 16. A reflective film or coating is on the reflective surface. The coating may be a reflective paint, for example. The use of mirrors is avoided, which would significantly add to the weight and cost of the solar dish collector system 10.

The dimensions of a solar dish collector system 10 vary depending on the intended application. The selected dimensions typically allow for easy portability. For illustration purposes, the solar dish collector system 10 may be 8 feet wide by 8 feet deep by 4 feet tall, for example.

To allow the solar dish collector panel 12 to track the sun from horizon to horizon, the base 14 has a triangular shape, as illustrated in FIG. 1. In addition, the base 14 uses less material as compared to a rectangular shape which in turn advantageously reduces weight and costs.

A jackscrew or tilting device 51 may be carried by each conduit support 44 and 46 for adjusting the angle of the solar dish collector system 10 to compensate for the seasonal rotation of the sun. This rotation may be limited to within plus/minus 10 degrees, for example. A controller 35 is connected to the jackscrews or tilting devices 43 for control thereof so that each conduit support 44, 46 is incrementally adjusted to provide the desired rotation, as readily appreciated by those skilled in the art. One controller 35 may control the jackscrews or tilting devices 51 for a plurality of solar dish collector panels 12 making up the solar dish collector system 10. This advantageously maximizes collection of the solar energy from the sun by the solar dish collector system 10.

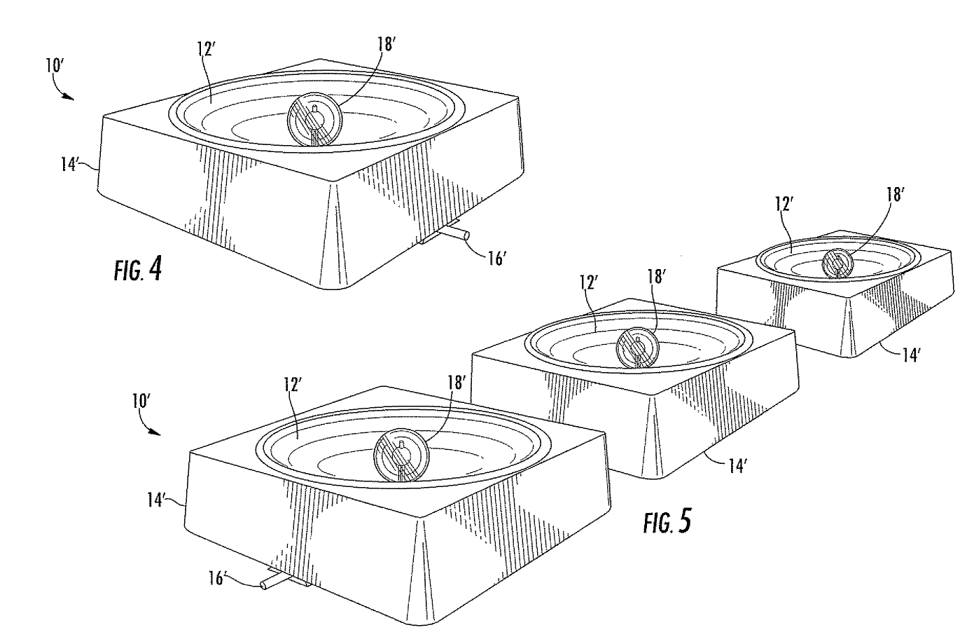

In another embodiment, the base 14′ of the solar dish collector system 10′ is rectangular shaped, as illustrated in FIG. 4. The rectangular shape is suited when placement of the solar dish collector system 10′ is on an angled roof, for example, and rotation from horizon to horizon is not necessary.

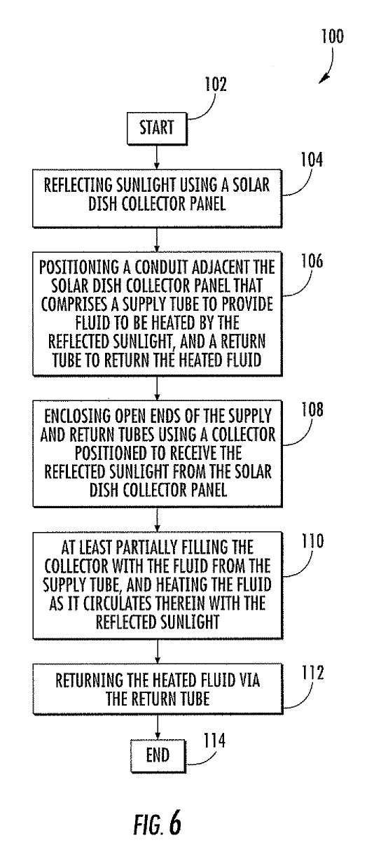

To achieve collection areas required for some applications, a plurality of solar dish collector system 10′ may be positioned side-by-side. As illustrated in FIG. 5, three solar dish collector system 10′ are connected to the same conduit 16′. The three solar dish collector systems 10′ are for illustration purposes, and the actual number of solar dish collector systems 10′ depends on the intended application. Even though the solar dish collector systems 10′ with a rectangular base 14′ are shown as being connected in series, the solar dish collector systems 10 with a triangular base 14 may also be used, as readily appreciated by those skilled in the art.

Another aspect is directed to a method for collecting solar energy using a solar energy collector system 10 as defined above. Referring now to the flowchart 100 illustrated in FIG. 6, from the start (Block 102), the method comprises reflecting sunlight using a solar dish collector panel 12 at Block 104. A conduit 16 is positioned adjacent the solar dish collector panel 12 at Block 106. The conduit 16 comprises a supply tube 20 to provide fluid to be heated by the reflected sunlight, and a return tube 22 to return the heated fluid.

The open ends of the supply and return tubes 20, 22 are enclosed at Block 108 using a collector 18 positioned to receive the reflected sunlight from the solar dish collector panel 12. The fluid from the supply tube 20 at least partially fills the collector 18 at Block 110, and is heated by the reflected sunlight while circulating therein. The heated fluid may then be returned via the return tube 22 at Block 112. The method ends at Block 114.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the foregoing description.

That which is claimed:

1. A solar dish collector system comprising:
a solar dish collector panel for reflecting sunlight;
a conduit adjacent said solar dish collector panel and comprising a supply tube to provide fluid to be heated by the reflected sunlight, and a return tube to return the heated fluid; and
a collector enclosing open ends of said supply and return tubes and positioned to receive the reflected sunlight from said solar dish collector panel, with the fluid from said supply tube at least partially filling said collector and being heated by the reflected sunlight while circulating therein, and with the heated fluid being returned via said return tube.

2. The solar dish collector system according to claim 1 wherein said solar dish collector panel is configured to reflect the sunlight to a focal point, and wherein said collector is positioned at the focal point.

3. The solar dish collector system according to claim 1 wherein said conduit extends below said solar dish collector panel; and wherein said supply and return tubes of said conduit extend upwards through said solar dish collector panel.

4. The solar dish collector system according to claim 3 wherein said solar dish collector panel is coupled to said conduit; and further comprising at least one actuator coupled to said conduit for pivotally rotating said conduit so that said solar dish collector panel tracks position of the sun.

5. The solar dish collector system according to claim 4 further comprising a sun sensor for tracking position of the sun; and wherein said at least one actuator rotates said solar dish collector panel based on the position of the sun.

6. The solar dish collector system according to claim 1 wherein the open ends of said supply and return tubes are spaced apart from one another within said collector, with the open end of said supply tube being positioned below the open end of said return tube.

7. The solar dish collector system according to claim 1 wherein said collector is configured as a sphere.

8. The solar dish collector system according to claim 1 wherein said collector comprises a clear material on sides thereof to receive the reflected sunlight, and comprises an opaque coating on a top portion thereof to prevent the reflected sunlight from escaping.

9. The solar dish collector system according to claim 1 further comprising an interior collector positioned within said collector for receiving the reflected sunlight, and for directly contacting the fluid to thereby increase solar consumption within said collector.

10. The solar dish collector system according to claim 9 wherein said interior collector is opaque.

11. The solar dish collector system according to claim 9 wherein outer surfaces of said interior collector comprise at least one of dimpled and corrugated outer surfaces.

12. The solar dish collector system according to claim 9 wherein said interior collector is hollow and includes a plurality of openings therethrough.

13. The solar dish collector system according to claim 1 wherein said solar dish collector panel comprises a reflective surface comprising at least one of a reflective film and a reflective coating.

14. The solar dish collector system according to claim 4 further comprising at least one tilting device for adjusting a latitudinal angle of said at least one conduit with respect to ground.

15. The solar dish collector system according to claim 1 further comprising a protective top over said collector for protection thereof.

16. The solar dish collector system according to claim 1 further comprising a photovoltaic cell within said collector for generating electricity.

17. A solar dish collector system comprising:
at least one solar dish collector panel for reflecting sunlight;
a conduit extending below said at least one solar dish collector panel and comprising a supply tube that extends upwards through said at least one solar dish collector panel to provide fluid to be heated by the reflected sunlight, and a return tube that extends upwards through said at least one solar dish collector panel to return the heated fluid; and
at least one collector enclosing open ends of said supply and return tubes and positioned to receive the reflected sunlight from said at least one solar dish collector panel to thereby heat the fluid circulating therein.

18. The solar dish collector system according to claim 17 wherein the fluid from said supply tube at least partially fills said collector.

19. The solar dish collector system according to claim 17 wherein said solar dish collector panel is configured to reflect the sunlight to a focal point, and wherein said collector is positioned at the focal point.

20. The solar dish collector system according to claim 17 wherein said at least one solar dish collector panel is coupled to said conduit; and further comprising at least one actuator coupled to said conduit for pivotally rotating said conduit so that said at least one solar dish collector panel tracks position of the sun.

21. The solar dish collector system according to claim 17 wherein the open ends of said supply and return tubes are spaced apart from one another within said collector, with the open end of said supply tube being positioned below the open end of said return tube.

22. The solar dish collector system according to claim 17 wherein said collector is configured as a sphere.

23. The solar dish collector system according to claim 17 further comprising an interior collector positioned within said collector for receiving the reflected sunlight, and for directly contacting the fluid to thereby increase solar consumption within said collector.

24. The solar dish collector system according to claim 23 wherein outer surfaces of said interior collector comprise at least one of dimpled and corrugated outer surfaces.

25. The solar dish collector system according to claim 23 wherein said interior collector is hollow and includes a plurality of openings therethrough.

26. The solar dish collector system according to claim 17 further comprising a protective top over said collector for protection thereof.

27. The solar dish collector system according to claim 17 further comprising a photovoltaic cell within said collector for generating electricity.

28. A method for collecting solar energy using a solar energy collector system, the method comprising:
reflecting sunlight using a solar dish collector panel;
positioning a conduit adjacent the solar dish collector panel that comprises a supply tube to provide fluid to be heated by the reflected sunlight, and a return tube to return the heated fluid; and
enclosing open ends of the supply and return tubes using a collector positioned to receive the reflected sunlight from the solar dish collector panel, with the fluid from the supply tube at least partially filling the collector and being heated by the reflected sunlight while circulating therein, and with the heated fluid being returned via the return tube.

29. The method according to claim 28 wherein the solar dish collector panel is configured to reflect the sunlight to a focal point, and wherein the collector is positioned at the focal point.

30. The method according to claim 28 wherein the conduit extends below the solar dish collector panel; and wherein the supply and return tubes of the conduit extend upwards through the solar dish collector panel.

31. The method according to claim 30 wherein the solar dish collector panel is coupled to the conduit; and the solar energy collector system further comprising at least one actuator coupled to the conduit for pivotally rotating the conduit so that the solar dish collector panel tracks position of the sun.

32. The method according to claim 28 wherein the collector is configured as a sphere.

33. The method according to claim 28 wherein the collector comprises a clear material on sides thereof to receive the reflected sunlight, and comprises an opaque coating on a top portion thereof to prevent the reflected sunlight from escaping.

34. The method according to claim 28 wherein the solar energy collector system further comprises an interior collector positioned within the collector for receiving the reflected sunlight, and for directly contacting the fluid to thereby increase solar consumption within the collector.
